(19) United States
(12) Patent Application Publication
(10) Pub. No.: US 2024/0272253 A1
(43) Pub. Date: Aug. 15, 2024

(54) MINIATURIZED MAGNETIC FIELD SENSOR

(71) Applicants: PRESIDENT AND FELLOWS OF HARVARD COLLEGE, Cambridge, MA (US); THE GENERAL HOSPITAL CORPORATION, Boston, MA (US)

(72) Inventors: Donhee HAM, Cambridge, MA (US); Bruce ROSEN, Boston, MA (US); Yi-Qiao SONG, Boston, MA (US)

(73) Assignees: PRESIDENT AND FELLOWS OF HARVARD COLLEGE, Cambridge, MA (US); THE GENERAL HOSPITAL CORPORATION, Boston, MA (US)

(21) Appl. No.: 18/681,031

(22) PCT Filed: Aug. 4, 2022
(86) PCT No.: PCT/US2022/039490

§ 371 Date: Feb. 2, 2024

Related U.S. Application Data
(60) Provisional application No. 63/229,917, filed on Aug. 5, 2021.

(51) Int. Cl. G01R 33/30; G01R 33/24; G01R 33/58

(52) U.S. Cl. CPC G01R 33/302; G01R 33/243; G01R 33/58

(57) ABSTRACT

A magnetic field monitoring system can include a host system that generates a magnetic field. The magnetic field monitoring system can include a plurality of sensor assemblies disposed apart from each other within the host system. Each of the plurality of sensor assemblies can include a coil wound around a sample and an integrated circuit coupled with the coil. The integrated circuit can perform one or more MR measurements of the sample using one or more pulse sequences.

### CROSS-REFERENCE TO RELATED PATENT APPLICATIONS

This application claims the benefit and priority of U.S. Provisional Patent Application No. 63/229,917, filed on Aug. 5, 2021, the entirety of which is incorporated by reference herein.

### GOVERNMENT RIGHTS

This invention was made with government support under DE-AR0001063 awarded by U.S. Department of Energy and under EB030006 awarded by the National Institutes of Health. The government has certain rights in the invention.

### TECHNICAL FIELD

The present application relates generally to measurement of magnetic fields and its time variation.

### BACKGROUND

Magnetic resonance (MR) and Magnetic resonance imaging (MRI) can be used in different areas of medicine for diagnostics and staging of diseases, and to monitor the progression of diseases and treatment.

### SUMMARY

MRI signals and images can be obtained from MRI scanners. The MRI scanners can include equipment (e.g., hardware) such as magnets to produce a static magnetic field, radiofrequency (RF) electronics to generate pulses of RF magnetic fields, and gradient electronics to produce pulses of direct current (DC) magnetic fields and gradients. The operation of this hardware in concert can produce signals that originate from the hydrogen atoms in the samples (e.g., patients, targets, etc.). These signals can then be processed to produce images. The measurement of magnetic fields and its time variation can have applications in nuclear magnetic resonance (NMR) and magnetic resonance imaging (MRI), such as medical MRI.

At least one aspect of the present disclosure is directed to a magnetic field monitoring system. The magnetic field monitoring system can include a host system that generates a magnetic field. The magnetic field monitoring system can include a plurality of sensor assemblies disposed apart from each other within the host system. Each of the plurality of sensor assemblies can include a coil wound around a sample and an integrated circuit (IC) coupled with the coil. The IC can perform one or more MR measurements of the sample using one or more pulse sequences.

Another aspect of the present disclosure is directed to a method of monitoring a magnetic field. The method can include providing a host system that generates a magnetic field. The method can include disposing a plurality of sensor assemblies apart from each other within the host system. Each of the plurality of sensor assemblies can include a sample disposed in a sample holder and an IC. The method can include performing, by the IC, one or more MR measurements of the sample using one or more pulse sequences.

Those skilled in the art will appreciate that the summary is illustrative only and is not intended to be in any way limiting. Other aspects, inventive features, and advantages of the devices and/or processes described herein, as defined solely by the claims, will become apparent in the detailed description set forth herein and taken in conjunction with the accompanying drawings.

### BRIEF DESCRIPTION OF THE DRAWINGS

The details of one or more implementations of the subject matter described in this specification are set forth in the accompanying drawings and the description below. Other features, aspects, and advantages of the subject matter will become apparent from the description, the drawings, and the claims.

FIG. 1 illustrates a schematic of a pulse sequence of a spin-echo imaging sequence, according to an embodiment.

FIG. 2 illustrates a schematic of a pulse sequence of an echo-planar imaging method, according to an embodiment.

FIG. 3 illustrates a schematic of a pulse sequence of diffusion MRI based on spin-echo imaging, according to an embodiment.

FIG. 4 illustrates a schematic of a printed circuit board layout of a sensor assembly, according to an embodiment.

FIG. 5 illustrates a plot of the positions of sensor assemblies in a spherical assembly, according to an embodiment.

FIG. 6 illustrates a plot of the positions of sensor assemblies in a cylindrical assembly, according to an embodiment.

FIG. 7 illustrates a magnetic field monitoring system, according to an embodiment.

FIG. 8 illustrates a method of monitoring a magnetic field, according to an embodiment.

Like reference numbers and designations in the various drawings indicate like elements.

### DETAILED DESCRIPTION

Following below are more detailed descriptions of various concepts related to, and implementations of, methods, apparatuses, and systems for the measurement of magnetic fields and its time variation. The various concepts introduced above and discussed in greater detail below may be implemented in any of a number of ways, as the described concepts are not limited to any particular manner of implementation. Examples of specific implementations and applications are provided primarily for illustrative purposes.

Magnetic resonance phenomenon can involve the application of static and RF magnetic fields to an object (e.g., patient, sample, target, etc.) that can impact the magnetic moment (e.g., spin) of a hydrogen atom (e.g., the hydrogen atom nucleus, the proton, etc.) in the object. The static magnetic field can cause the spins of atoms in the object to align along and oscillate (e.g., precess) about the axis of the applied magnetic field. The spin magnetization of the atoms can be measured. The return to equilibrium of this magnetization (e.g., longitudinal relaxation) can be due to energy exchange between the spins of the atoms and the surrounding lattice (e.g., spin-lattice relaxation), and can be denoted by a time T1 when the longitudinal magnetization has returned to a predetermined percentage (e.g., 63%) of its final value. Longitudinal relaxation can involve the component of the spin parallel or anti-parallel to the direction of the magnetic field. The transverse relaxation can result from spins getting out of phase. The characteristic time can be denoted by T2 when the transverse magnetization has lost a predetermined percentage (e.g., 63%) of its original value. The transverse relaxation can involve the components of the spin oriented orthogonal to the axis of the applied magnetic field. The T2 measurement can be performed using the spin-echo pulse sequence which involves one 90-degree pulse followed by one 180-degree refocusing pulse. The T2 can be also measured using Carr-Purcell-Meiboom-Gill (CPMG) pulse sequence which utilizes an initial 90-degree excitation pulse (e.g., p90) followed by a series of 180-degree (e.g., pi) pulses (e.g., p180).

The signals and thus the images can be affected by various physical phenomena of the molecular dynamics of the hydrogen-carrying molecules, such as water and fat molecules. The phenomena can include, for example, spin-lattice relaxation, spin-spin relaxation, and diffusion of the molecules. Spin-lattice relaxations can be characterized by time constant, T1. Spin-spin relaxations can be characterized by time constant, T2. The diffusion can be characterized by the diffusion constant, D. Different tissues and tissues at different stages of a disease can exhibit different values of T1, T2, and D. For example, in brain tumor such as glioma, the tumor tissue can exhibit a significantly longer T2 and T1 than normal brain tissues. As a result, such enhanced T1 and T2 values can be used as a signature of the tumor to quantify the size of the tumor and the stage of the tumor progression. During treatment, MRI images can provide evidence for the shrinkage of the lesion and thus the effectiveness of the treatment regimen. Such monitoring can be useful to monitoring and fine tuning the treatment plan.

Diffusion can be useful to detect the tissue microstructure and can be used to differentiate different types of tissues within the cancer region. This can be due to the fact that water molecular diffusion is hindered or restricted by the presence of cells, blood vessels and other structures inside tissues. For example, water molecules inside axons can diffuse relatively freely along the axon axis, however, the diffusion transverse to the axon axis can be much restricted. As a result, angular measurement of the diffusion coefficient can allow MRI to identify axon directions and white matter tracks. A disease tissue (e.g., cancer) can exhibit different microstructure compared to the normal tissue and thus the water diffusion behavior can be altered.

Magnetic resonance systems can employ a magnet that produces a static magnetic field. For MRI or diffusion measurements, additional pulsed magnetic field gradient systems can be used. Such gradient systems can include coils and electronics to produce electrical current to feed into the coils and to produce pulsed magnetic field and field gradients. The gradient can include a slope in the magnetic field as a function of the spatial coordinates. However, due to the limitation of the bandwidth of the electronics and their power, the pulses of the gradients and magnetic fields often do not accurately reflect the designed waveforms. In addition, eddy current generated in the metallic structures near the gradient coils can further degrade the magnetic field in the sample region in the form of a shift in the magnetic field and the appearance of additional gradients. As a result, the resulting image and diffusion measurements can be compromised and degraded in resolution and inaccuracy.

The systems and methods of the present disclosure, in some embodiments, relate to the concept of a small (e.g., miniaturized) NMR-based magnetic field sensor (e.g., sensor assembly) that can be placed inside a large MRI system (e.g., host system) to monitor the magnetic field during an MR experiment. Several sensors can be distributed around the sample to detect, measure and/or characterize the magnetic field at different positions. This data can be used to improve the MRI image quality and measurement accuracy.

MRI properties of tissues can include spin-lattice relaxation time (T1), spin-spin relaxation time (T2), and diffusion coefficient (D). Each can be measured by specific pulse sequences and MRI experiments.

For the T1 measurement, methods to obtain T1 can include the inversion-recovery (IR) method and the saturation-recovery (SR) method. For the IR method, the pulse sequence can be described in Equation 1:

$$RD - p 180 - WT - p 90 - ACQ \qquad ( 1 )$$

The first time period RD can be long (e.g., several times the T1 of the sample) for the system to recover to thermal equilibrium. The p180 pulse can invert the magnetization. The time WT can allow the magnetization (M) to relax according to Equation 2:

$$M ( WT ) = {M}_{0} \{ 1 - 2 exp [ - \frac{WT}{{T}_{1}} ] \} , \qquad ( 2 )$$

where M₀ is the equilibrium magnetization of the sample. The magnetization can be measured after the data acquisition (ACQ) after the p90 degree pulse. Several measurements of the signal for a series values of WT can be obtained to determine the T1 of the sample.

Furthermore, imaging pulse sequences combining RF pulses and gradient pulses can be applied after the WT in Equation 1 to produce MRI images. In this case, Equation 2 can be applied to each voxel of the image. When several images with different WT are obtained, T1 can be obtained for each and all voxels to obtain a spatial map of T1 of the sample.

For the SR method, the pulse sequence can be described by Equation 3:

$$WT - p 90 - ACQ \qquad ( 3 )$$

The magnetization at the beginning of WT period can be zero due to the saturation in the previous experiment or by additional pulses to saturate. The magnetization can recover during the time WT according to Equation 4:

$$M ( WT ) = {M}_{0} \{ 1 - exp [ - \frac{WT}{{T}_{1}} ] \} , \qquad ( 4 )$$

Similar to the IR method, image method and pulse sequences can be added to obtain an image of the sample.

For the measurement of T2, a spin-echo pulse sequence is can be used, which can be described by Equation 5:

$$RD - p 90 - TE / 2 - p 180 - TE / 2 - ACQ \qquad ( 5 )$$

The time period TE is called echo time, and the time spacing between the p90 and p180 is half TE (as marked TE/2). The magnetization can decay as a function of TE according to Equation 6:

$$M ( TE ) = {M}_{0} exp [ - \frac{TE}{{T}_{2}} ] , \qquad ( 6 )$$

where M₀ is the magnetization when TE/T2 approaches 0. Similar to the T1 measurement described above, when several measurements with different TE are obtained, the value of T2 of a sample can be obtained.

In addition to the spin-echo sequence, a CPMG sequence can be used with multiple p180 pulses to generate a train of echoes. The echo time for echo number n is n*TE. For example, for the first echo, n=1 and for the 10^{th} echo, n=10. As a result, with one experiment, several data points of the signal decay can be obtained and thus accelerate the measurement of T2.

The molecular diffusion property can reflect the molecular composition as well as the physical and fluidic environment. For example, when a water molecule is in a viscous fluid, its diffusion coefficient, D, can decrease. When fluid is inside porous materials or tissues, the water diffusion can be restricted due to the presence of solid materials or membranes. The diffusion coefficient can be substantially decreased from the value in the bulk fluid. As a result, the measurement of diffusion coefficient can be used to characterize porous materials and tissue microstructures.

Diffusion can be measured using the spin-echo sequence (e.g., Equation 5) with additional field gradient pulses during the two time periods, the first pulse between p90 and p180 and the second pulse between p180 and ACQ. The magnetization decay due to diffusion can be described by Equation 7:

$$M ( b ) = {M}_{0} exp [ - bD ] , \qquad ( 7 )$$

where D is the diffusion coefficient, and b is the diffusion weighting determined by the pulse sequence and in particular the field gradient pulses used. Similar to the T1 and T2 measurements, several signals with different b values can be obtained to determine D. The diffusion coefficient can be different along different directions in anisotropic tissues, such as white matter. The diffusion tensor imaging method (DTI) can apply a field gradient along different directions to obtain the diffusion tensor.

In a tissue, many different components can be present within a single voxel of the image. These different components can exhibit different value of the diffusion coefficient so that the total signal is the sum of all components, which can be described by Equation 8:

$$M ( b ) / {M}_{0} = {{\sum }^{N}}_{i = 1} {w}_{i} exp [ - {bD}_{i} ] , \qquad ( 8 )$$

where Dᵢ is the diffusion coefficients of the i^{th} component and wᵢ is its weight and N is the total number of components. For example, in neuroimaging and interpretation, three components can be considered: (1) the signal associated with the axon with an anisotropic diffusion behavior, (2) the signal associated with the tissue so that the diffusion is restricted and isotropic, and (3) the signal from unrestricted water pool.

MRI technology can employ static magnetic field and pulsed magnetic fields in addition to RF magnetic fields to acquire images of the body and determine the tissue properties. The static magnetic field can be provided by a large coil of superconductor (e.g., NbTi or Nb₃Sn) immersed in a cryogenic fluid (e.g., liquid helium). This static magnetic field can be adjusted to become spatially highly uniform such that the field variation within the imaging volume is within 1 ppm for small imaging volumes and 5 ppm for clinical scanners. This high uniformity may be required for high resolution images. A degradation of this uniformity can cause image distortion and loss of signal-to-noise ratio. A separate shim coil system can be installed in the magnet to further correct the static field to achieve high field uniformity.

In addition to the static field, the pulsed field gradient system can be used for image acquisition and performance of diffusion measurements. Three gradient coils can be used to produce gradients along the three Cartesian axes, X, Y, and Z. Each coil can be electrically connected to a power amplifier to provide electrical current to generate the gradient. For example, the magnetic field generated by these gradient coils can be linear in the spatial coordinates, which can be described by Equation 9:

$${B}_{z} = {g}_{x} X + {g}_{y} Y + {g}_{z} Z \qquad ( 9 )$$

where the z direction in B_{z} is the direction along which the main static field from the superconducting magnet is applied.

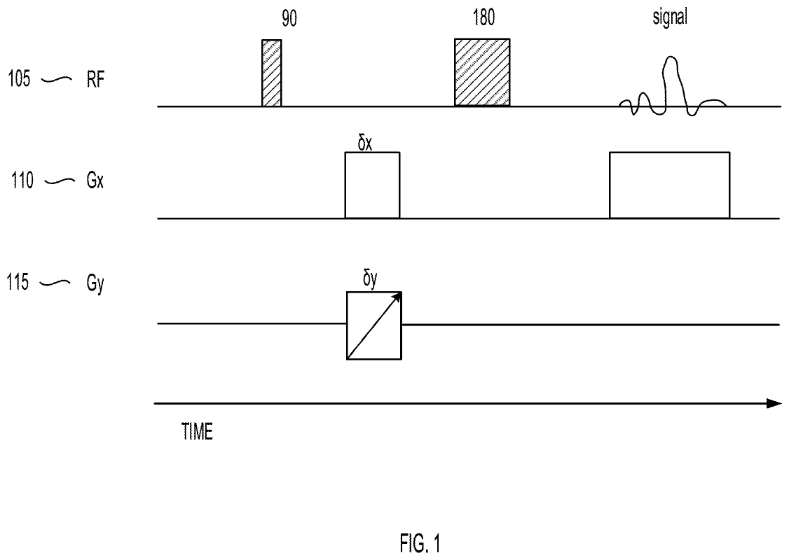

The pulse sequence of spin-echo imaging method (e.g., sequence) can be shown in FIG. 1. Radiofrequency (RF) pulse events and data acquisition 105, X-gradient pulse sequence 110, and Y-gradient pulse sequence 115 can be shown. The 90 and 180 degrees pulses can produce a spin-echo signal to be acquired. The Gₓ line can describe the X-gradient sequence. The G_{y} line can describe the Y-gradient sequence. The amplitude of the Y-gradient pulse can be g_{y}. The measurement can be performed with a series of g_{y} values. The time between the 90 and 180 degrees pulses can be defined to be TE/2. The signal can be acquired near the time of the spin-echo which is TE/2 after the 180 degrees pulse. The acquisition time t can be defined to be zero at the time of the spin-echo.

The signal of the experiment shown in FIG. 1 can be described as follows by Equation 10:

$$S ( t , {g}_{y} ) = \int dr \cdot f ( x , y ) exp ( - i γ {g}_{x} xt - i γ {g}_{y} {δ}_{y} y ) , \qquad ( 10 )$$

where γ is the gyromagnetic ration of hydrogen, t is the acquisition time which is set to zero at the center of the echo, and δ_{y} is the duration of the G_{y} pulse. f(x, y) is the density of the hydrogen atoms in the sample, and x and y are the Cartesian coordinates of the sample. Thus, f(x, y) can be the desired image to be acquired. The image data can be obtained by acquiring the echo data S (as a function of t) for a series of g_{y} gradient values. The data acquisition during a constant gradient (such as for gₓ in FIG. 1) can be called a frequency encoding method corresponding to exp(−iγgₓxt) in Equation 10, and the measurements with different g_{y} can be called a phase encoding method corresponding to the exp(−iγg_{y}δ_{y}y) term in Equation 10.

The acquired data can be a two-dimensional matrix, S(t, g_{y}). The following parameters can be defined:

$${k}_{x} ≡ γ {g}_{x} t , and {k}_{y} ≡ γ {g}_{y} {δ}_{y} \qquad ( 11 )$$

Then Equation 10 can be rewritten as Equation 12:

$$S ( {k}_{x} , {k}_{y} ) = \int dr \cdot f ( x , y ) exp ( - {ik}_{x} x - {ik}_{y} y ) \qquad ( 12 )$$

Mathematically, an inverse Fourier transform of the data matrix S(kₓ, k_{y}) can be used to obtain the image, f(x, y). The method can assume the ideal performance of the pulsed field gradient system to provide the gradient waveform as illustrated in FIG. 1. For example, kₓ and k_{y} can be sampled at equal distances so that a Fast Fourier transformation can be directly used to obtain the image. In addition, a pulsed magnetic field can generate eddy current in the metallic structure around the coils, such as the cryogenic container that houses the magnet. The gradient electronics can contain compensation circuitry to control and maximize the slew rate (e.g., how quickly the current can ramp up) and avoid oscillations. Furthermore, pulse sequence design may replace the single rising edge of the pulse into several smaller steps to slow down the ramp up and thus reduce eddy current. The same method can be used for the falling edge of the gradient pulses. However, these methods can make the gradient pulse longer and may degrade the image quality and resolution.

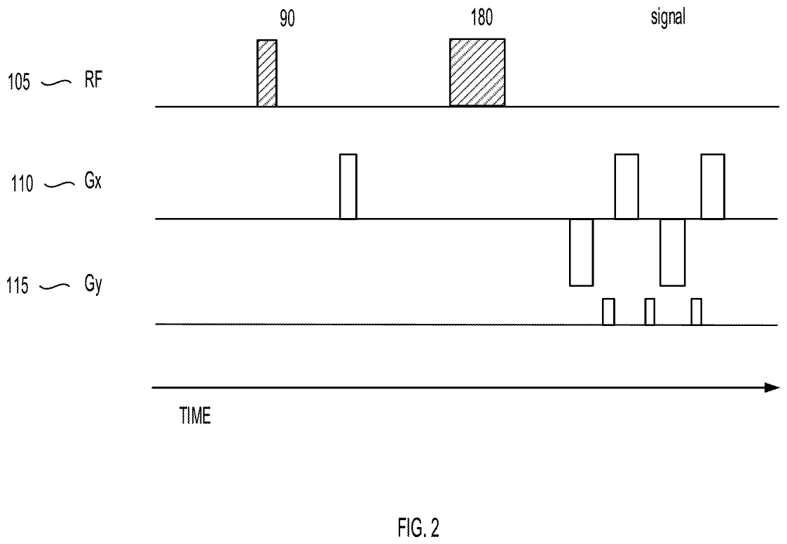

Many other MRI methods, such as echo-planar imaging (EPI), can be used in medical imaging. The EPI method, as shown in FIG. 2, can use a series of reversing gradients to create a train of gradient echoes. Each echo can be further modulated by a small blip G_{y} pulse which can provide phase encoding. The EPI pulse sequence can be understood as a different approach to sample the k-space (e.g., kₓ and k_{y} in FIG. 1) to achieve the measurement of the S(kₓ, k_{y}) and then subsequently to obtain the image, f(x, y).

To consider the non-ideal magnetic field gradient pulses, the image equation, Equation 10, can be rewritten for the frequency encoding term, as described by Equation 13:

$$S ( t , {g}_{y} ) = \int dr \cdot f ( x , y ) exp ( - i {ϕ}_{fe} ( x , y , {g}_{x} , t ) - i {ϕ}_{ph} ( x , y , {g}_{y} , {δ}_{y} ) ) \qquad ( 13 )$$

where ϕ_{fe} and ϕₚₕ are the phases from frequency and phase encoding parts of the sequence, as described by Equation 14a and Equation 14b:

$${ϕ}_{fe} = γ b ( x , y , t ) t , \qquad ( 14 a )$$

$${ϕ}_{ph} = \int {dt}^{′} \cdot γ b ( x , y , {t}^{′} ) {t}^{′} \qquad ( 14 b )$$

The phase encoding part can be integrated during the phase encoding pulse of g_{y}. b(x, y, t) is the magnetic field at position x, y, and time t. The magnetic field can be known at all times t and all coordinates. The exponential term exp(−iϕ_{fe}−iϕₚₕ) can be a known function and thus Equation 13 can be solved by various methods, such as various least-square fitting methods with or without constraints, or regularization based inversion methods (e.g., Tikhonov regularization). This inversion can be similar to the methods used in compressed sensing for image reconstruction.

Other methods can also be used. For example, if the correction to the magnetic field is small, Equation 13 can be used to define kₓ and k_{y} except that the gradient may vary slightly in space. This can correspond to a deviation in the kₓ and k_{y} samples from ideal equal-distance sampling. Resampling of the data by interpolation can recover the equal kₓ and k_{y} sampling to use the conventional image reconstruction algorithm.

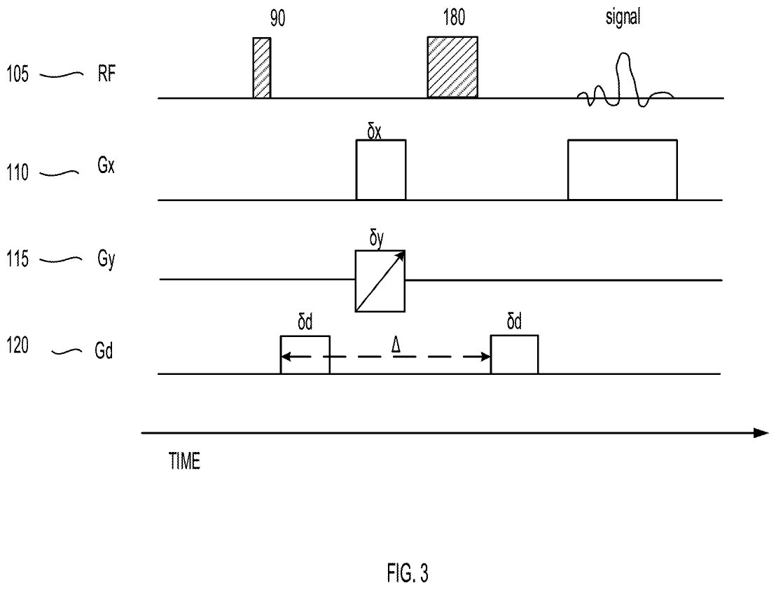

Diffusion MRI can be another technique that uses pulsed field gradients. An example pulse sequence for diffusion measurement is illustrated in FIG. 3 which is a spin-echo imaging sequence with additional pulses for diffusion (G_{d}). FIG. 3 illustrates a schematic of a pulse sequence of diffusion MRI based on spin-echo imaging. The G_{d} line 120 can indicate the gradient sequence for diffusion encoding.

The presence of the pair of diffusion gradient pulses can exhibit an additional decay of the signal as Equation 15:

$$S ( {g}_{d} ) = S ( 0 ) exp [ - {γ}^{2} {g}_{d}^{2} {δ}_{d}^{2} ( Δ - \frac{{δ}_{d}}{3} ) ] \qquad ( 15 )$$

where g_{d} is the amplitude of the G_{d} pulses. For many diffusion measurements (e.g., kurtosis and other methods to probe the microstructure of tissues), high diffusion gradients may be required. Such high gradient values can exacerbate the issues due to the gradient performance limitation and eddy current effects.

Correction for the image distortion due to diffusion gradient pulses can be performed using the method discussed above using Equation 13, Equation 14a, and Equation 14b. Furthermore, the real local field gradients can be obtained from the field measurement and such calibrated field gradients can be used to analyze the diffusion data.

Even though the above examples can specify a few pulse sequences and describe them in term of specific gradient directions, MRI can be performed along any X, Y, and Z directions or other oblique planes for both 2D and 3D imaging. The methods described herein can also be expanded to different directions for 2D and 3D imaging.

To reduce the gradient pulse imperfection and improve the resolution of MRI, the methods described herein introduce miniaturized magnetic field sensors around the sample to record the magnetic field and gradients during the execution of the MRI pulse sequence. The miniaturized magnetic field sensor (MMFS) can include a miniaturized NMR system to measure the magnetic field and its time variation. The NMR signal frequency can be proportional to the local magnetic field at the position of the miniaturized magnetic field sensor, which is described by Equation 16,

$$ω ( t ) = γ [ {B}_{0} + b ( x , y , z , t ) ] \qquad ( 16 )$$

where B₀ is the static magnetic field and b(x,y,z,t) is the time-varying part of the local magnetic field at the coordinate x, y, z, and time t. ω(t) is the instantaneous frequency as it varies during the pulse sequence. As a result, the signal of an NMR sample at position x, y, and z coordinates after a 90-degree pulse can be described by Equation 17,

$$S ( x , y , z , t ) = exp [ - i γ b ( x , y , z , t ) t ] \qquad ( 17 )$$

The B₀ part of the signal modulation can be removed by the spectrometer electronics and data processing algorithm. The instantaneous frequency, ω(t), can be obtained by a time-derivative of the signal. Placement of miniaturized magnetic field sensors at multiple positions near the position of the sample can allow for an accurate measurement of the magnetic field within the imaging volume. Miniaturized magnetic field sensor data can include the magnetic field data obtained by one or more miniaturized magnetic field sensors.

To measure the magnetic field at multiple positions, a small probe that includes a small sample, such as a sample with a diameter of about 1 mm, and a small coil around the sample can be used. Conventional designs of magnetic field sensors can use off-the-shelf electronic components for the NMR transmitter, receiver, data acquisition, and pulse sequence controllers. As a result, such an electronic system can be very bulky and expensive. These systems may have to be placed far away from the probes themselves which can cause signal degradation. The systems and methods of the present disclosure can resolve such problems by using a device corresponding to an IC or chip (e.g., an application specific integrated circuit (ASIC)), to perform all essential NMR functions including RF pulse transmission, RF signal reception, and digitization. As a result, the electronics for the miniaturized magnetic field sensor are much smaller compared with conventional sensors. The miniaturized magnetic field sensor can be placed next to (e.g., adjacent to, near, etc.) the sample to form a sensor assembly. The signal from the miniaturized magnetic field sensor can be digitized at the output of the probe assembly.

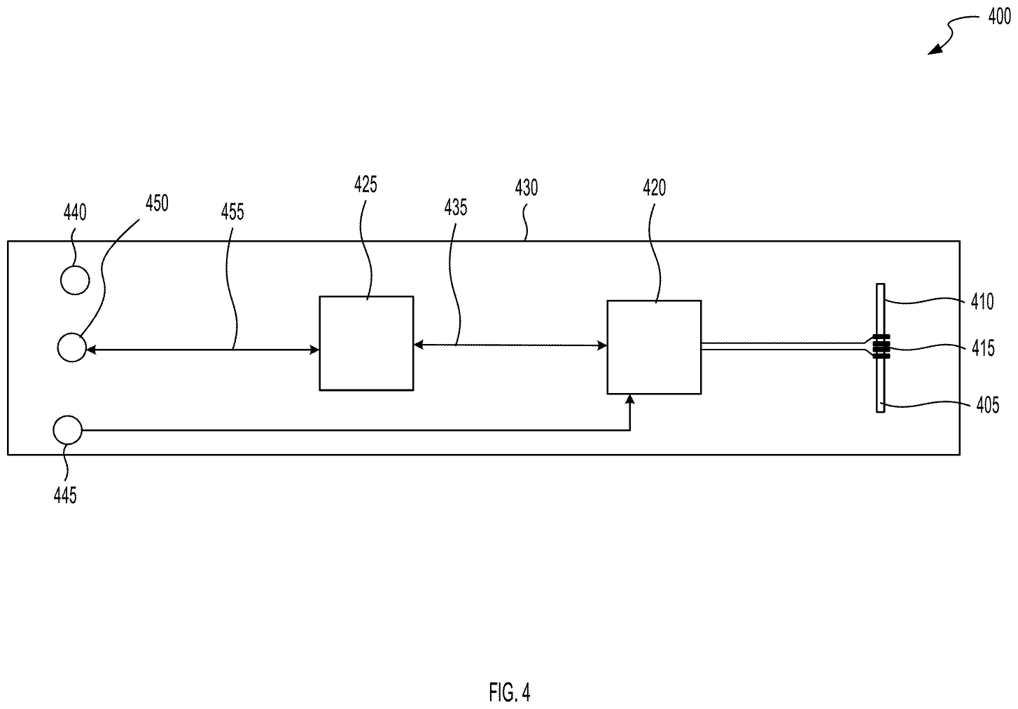

FIG. 4 illustrates a schematic of a printed circuit board layout of a sensor assembly 400 (e.g., probe assembly, sensor probe assembly, miniaturized magnetic field sensor, magnetic field sensor, etc.). The sensor assembly 400 can include a sample 405 (e.g., fluid sample). The sample 405 can contain a nuclear spin that is not affected by the main NMR/MRI (e.g., host system) excitation. For example, to be used for a clinical MRI which can excite and detect hydrogen spins, the spin for the sensor assembly 400 could be ¹⁹F or ²D. The sample 405 can be a liquid with a long T2 and T2*. The sample 405 can exhibit a strong signal, such as ¹⁹F. For example, the sample 405 can include low viscosity perfluorocarbon oil.

The sensor assembly 400 can include a sample holder 410 (e.g., sample capillary). The sample 405 can be placed in a sample holder 410. The sample 405 can be disposed in the sample holder 410. The sample holder 410 can include a tube, capillary, or bulb. For example, the sample holder 410 can include a thin-wall glass capillary tube, a tube made from PEEK, or a spherical shaped glass bulb. The size of the tube, capillary, or bulb of the sample holder 410 can be about 1 mm in diameter. The sample holder 410 can be a few millimeters in size. The inner surface of the tube, capillary, or bulb can be smooth and be free of defects or damage to avoid causing additional spin relaxation. For the capillary sample, the long axis of the capillary can align with the static magnetic field.

The sensor assembly 400 can include a coil 415. The coil 415 can be a solenoid. For example, the coil 415 can be a solenoid made with fine copper wires wrapped around the sample 405. The solenoid can have a few turns (e.g., 1-10). The size of the coil 415 can match the size of the sample 405. The length of the coil 415 can be 1 mm or a few mm. The sample holder 410 can include the coil 415.

The sensor assembly 400 can include various electronics. For example, the sensor assembly 400 can include an NMR application specific integrated circuit (ASIC) 420 (e.g., NMR ASIC, ASIC chip, ASIC, integrated circuit, etc.) or other IC device. The NMR ASIC 420 can contain circuitry that performs function of the NMR spectrometer, including the pulse sequence execution, RF pulse transmission, NMR (RF) signal reception, amplification, and down conversion. The NMR ASIC 420 may contain a frequency synthesizer, an RF phase generator, a variable gain amplifier, and/or an analog-to-digital converter (ADC). The NMR signal can then be digitized either within the NMR ASIC 420. The NMR ASIC 420 can integrate a digitally-programmable pulse sequencer, a digitally-controlled NMR transmitter, and a digitally-controlled NMR receiver as parts of a single integrated circuit chip within an area of about 4 mm². Other embodiments may use integrated circuit chips having different dimensions. The NMR ASIC 420 can be fabricated using commercially available process technology (such as the TSMC 0.18 μm process of Taiwan Semiconductor Manufacturing Company, Limited or TSMC). The NMR receiver can be temperature compensated so that the gain of the NMR receiver is insensitive to expected variations in temperature during operation of the NMR ASIC 420. This feature can improve performance of the NMR ASIC 420 at high temperatures.

The digitally-programmable pulse sequencer and the digitally-controlled NMR transmitter of the NMR ASIC 420 can be configured such that the NMR transmitter generates a wide variety of NMR pulse sequences (e.g., sequences of pulses of oscillating RF signals that are supplied to an external antenna to excite macroscopic nuclear spins in a sample). This feature can allow multiple NMR pulse sequences to be tested and used with the NMR ASIC 420 for different NMR experiments without hardware modification to the NMR ASIC 420.

The sensor assembly 400 can include a microcontroller 425 (e.g., microcontroller chip, microcontroller unit, etc.). A digital signal can be transmitted to the microcontroller 425 for processing. The digital signal can be stored in the microcontroller 425 or external memory. The digital signal can be transmitted to a host computer (e.g., an MRI console) to be used in image reconstruction. The microcontroller 425 can process the NMR signal. The microcontroller 425 can store the pulse sequences. For example, the microcontroller 425 can store the pulse sequences to be executed for the magnetic field measurement. The microcontroller 425 can be coupled to the NMR ASIC 420 via a digital link 435. The microcontroller 425 can issue digital commands and timing clock signals to the NMR ASIC 420 and/or peripheral components (e.g., RF switches). The microcontroller 425 can issue timing clock signals to the NMR ASIC 420 via the digital link 435. Examples of the microcontroller 425 can include the PIC32 family by Microchip, C2000 family by Texas Instruments, or other ARM-based microcontroller products. Other chips such as FPGA, digital signal processors (DSP) may also be used instead of microcontroller 425.

One or more microcontrollers 425 can be coupled with the sample 405 or sample holder 410. One or more NMR ASICs 420 can be coupled with the one or more microcontrollers 425. One or more NMR ASICs 420 can be coupled with the sample 405 or sample holder 410. One or more microcontrollers 425 can serve one or more NMR ASICS 420. One or more microcontrollers 425 can control one or more NMR ASICs 420. The microcontroller 425 can be separate from the NMR ASIC 420. The microcontroller 425 can be incorporated into the NMR ASIC 420. The microcontroller 425 can be integrated with the NMR ASIC 420.

The sensor assembly 400 can include supporting electronic components. For example, the supporting electronic components can include resistors. The supporting electronic components can include capacitors. The supporting electronic components can include RF switches.

The sensor assembly 400 can include a printed circuit board (PCB) 430 (e.g., PCB assembly). The PCB 430 can host (e.g., contain or include) components of the sensor assembly 400 including the sample holder 410, the coil 415, the NMR ASIC 420, and the microcontroller 425. Additional circuit components can be mounted on the PCB 430 to support the operation of the NMR ASIC 420 and the microcontroller 425. Magnetic components can be avoided in the PCB 430 because magnetic components (e.g., a magnetic core in an inductor/transformer) may not work in a high magnetic field of MRI magnets. Additionally, such magnetic components may alter the magnetic field and thus cause error in the measurement. For example, the PCB 430 may not include nickel plating.

The sensor assembly 400 can include a power supply 440 (e.g., power source). Power can be routed from the power supply 440 to the NMR ASIC 420. Power can be routed from the power supply 440 to the microcontroller 425. The sensor assembly 400 can be low power and consume a few watts of power. Thus, a low voltage power supply 440 (e.g., 5 V) can be sufficient to power the components of the sensor assembly 400.

The sensor assembly 400 can include an RF reference signal 445 (e.g., reference signal). A continuous wave RF signal can be provided to the NMR ASIC 420 as the reference signal to produce RF pulses and signal reception. The frequency of this reference signal can be the Larmor frequency of the miniaturized magnetic field sensor or twice the Larmor frequency. If the NMR ASIC 420 includes an internal frequency synthesizer, the reference signal may be from a stable crystal oscillator (e.g., 16 MHz) so that the frequency synthesizer in the NMR ASIC 420 can produce local oscillator signals with finely tunable frequencies for RF pulses and RF NMR signal down conversion.

The sensor assembly 400 can include a port 450. The port 450 can be coupled (e.g., connected) to a host system (e.g., host MRI system). To initiate the beginning of the field measurement, the miniaturized magnetic field sensor may use a trigger signal from the host MRI system. The trigger signal can occur right before the beginning of the first RF pulse or gradient pulse. This trigger signal can time-stamp the magnetic field measurements to be synchronized with the MRI data for image reconstruction. The port 450 can be coupled to the microcontroller 425 via a digital link 455. The digital link 455 can transmit data between the miniaturized magnetic field sensor and the host system. This digital link 455 can include a serial communication (e.g., RS-485, USB, Ethernet, etc.). The microcontroller can be coupled to (e.g., connected) the host system via the digital link 455.

The RF reference signal 445, power supply 440, and/or the trigger signal can be combined. The RF reference signal 445 and the trigger signal can be different frequencies. The RF reference signal 445 and the trigger signal can be separated on the PCB 430 using filters.

The electronics can be placed away from the sample 405 and the coil 415 to further reduce the size of the sensor assembly 400. For example, the electronics (e.g., NMR ASIC 420, microcontroller 425, etc.) can be placed between 30 cm and 100 cm away from the position of the sample 405 so that the electronics can be hosted together. However, a longer cable connecting the coil 415 and the electronics may cause some signal degradation.

To determine the magnetic field gradients, a plurality of sensor assemblies 400 can be placed at different distances from a center of an MRI magnet. For example, to characterize an X-gradient (e.g., x-gradient, gradient in x-direction, etc.), one or more sensor assemblies (e.g., one or more miniaturized magnetic field sensors) of the plurality of sensor assemblies 400 can be placed away from the center of the MRI magnet along the X-axis, for example, at X=10 cm, or two sensors at X=10 cm and X=−10 cm. The X-gradient can include the slope of the magnetic field in the x-direction. To characterize a Y-gradient (e.g., y-gradient, gradient in y-direction, etc.), one or more sensor assemblies (e.g., one or more miniaturized magnetic field sensors) of the plurality of sensor assemblies can be placed away from the center of the MRI magnet along the Y-axis, for example, at Y=10 cm, or two sensors at Y=10 cm and Y=−10 cm. The Y-gradient can include the slope of the magnetic field in the y-direction. To characterize a Z-gradient (e.g., z-gradient, gradient in z-direction, etc.), one or more sensor assemblies (e.g., one or more miniaturized magnetic field sensors) of the plurality of sensor assemblies 400 can be placed away from the center of the MRI magnet along the Z-axis, for example, at Z=10 cm, or two sensors at Z=10 cm and Z=−10 cm. The Z-gradient can include the slope of the magnetic field in the z-direction.

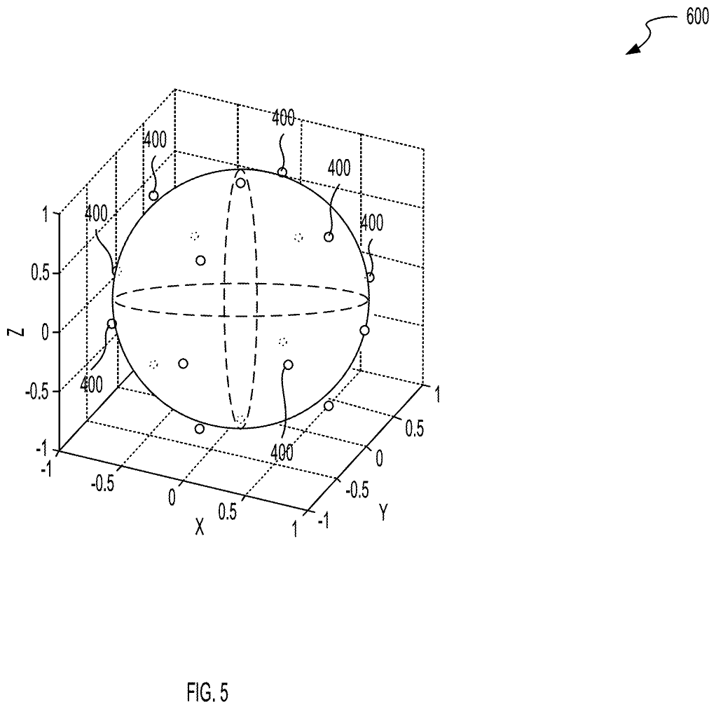

The magnetic field can be characterized by a series of terms, which can be expressed as a summation of spherical harmonics functions described in Equation 18,

$$b ( r , θ , φ ) = {{\sum }^{∞}}_{ℓ = 0} {{\sum }^{ℓ}}_{m = - ℓ} {f}_{ℓ}^{m} {r}^{ℓ} {Y}_{ℓ}^{m} ( θ , φ ) , \qquad ( 18 )$$

where, expressed in the spherical coordinate system, r is radial distance (e.g., distance to origin), θ is the polar angle (e.g., angle with respect to polar axis), and φ is the azimuthal angle (e.g., angle of rotation from the initial meridian plane). Each term in the summation can exhibit a specific angular dependence. Even though the maximum value of 1 in the summation can be very high, for MRI applications, it can be sufficient to characterize to l=2 or l=3. As a result, positioning the miniaturized magnetic field sensors over a sphere can be effective in determining the coefficients (fₗ^{m}), for example as shown in FIG. 5.

FIG. 5 illustrates a plot of the positions of sensor assemblies 400 in a spherical assembly 500. The positions of the sensor assemblies 400 are shown as dots in the spherical assembly 500 (e.g., spherical structure, spherical assembly arrangement, etc.). The positions of the sensor assemblies 400 can be an equal distance from the center of the sphere. The sphere is shown to help depict the sensor assemblies 400 clearly. The radius of the sphere is slightly smaller than the radial distance of the sensor assemblies 400. The sensor assemblies 400 can be used to determine the fₗ^{m} coefficients. Positioning the sensor assemblies 400 as the spherical assembly 500 can be useful for a measurement to calibrate the performance of the MRI scanner. However, since the sensor assemblies 400 can cover all around the sphere, it may not be a practical geometry to acquire magnetic field data while scanning a patient.

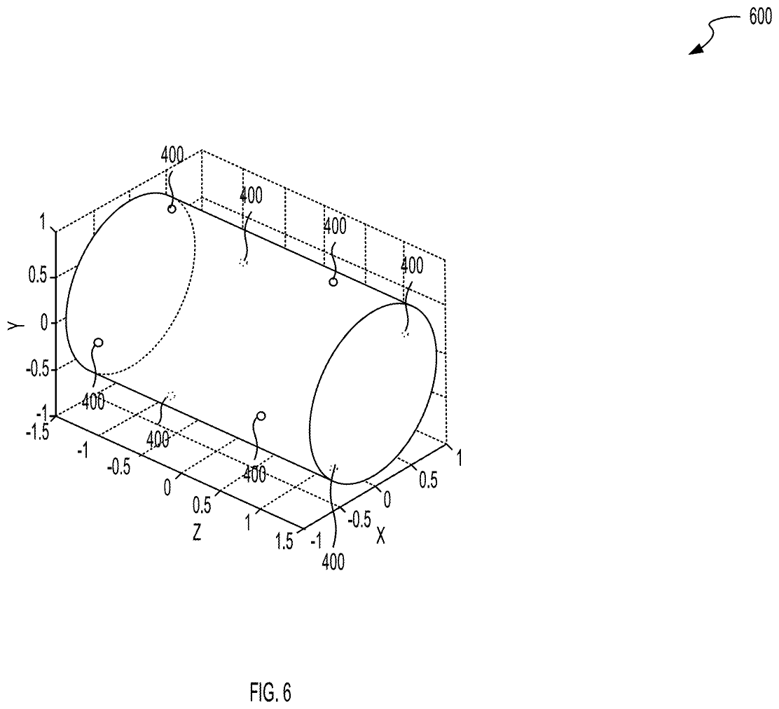

FIG. 6 illustrates a plot of the positions of sensor assemblies 400 in a cylindrical assembly 600. The positions of the sensor assemblies 400 are shown as dots in the cylindrical assembly 600 (e.g., cylindrical structure, cylindrical assembly arrangement, etc.). The position of the sensor assemblies 400 are shown as dots in the cylindrical assembly 600. The positions of the sensor assemblies 400 can be an equal distance from the center of the cylinder and around the cylinder. The cylinder is shown to help depict the sensor assemblies 400 clearly. This arrangement of sensor assemblies 400 can allow magnetic field measurements during MRI scans of patients. A total of eight sensor assemblies 400 are shown in FIG. 6. Fewer or more sensor assemblies 400 can be included in the cylindrical assembly 600 of sensor assemblies 400. This assembly may not be able to characterize the high order coefficients (fₗ^{m}), but can characterize to l=0 and l=1. This assembly can be used to monitor the performance of the gradient system during MRI. The center of the assembly of the multiple sensor assemblies 400 may not exactly coincide with the magnet center. The offset coordinates between the magnet center and the center of the assembly of sensor assemblies 400 may be obtained from the magnetic field data.

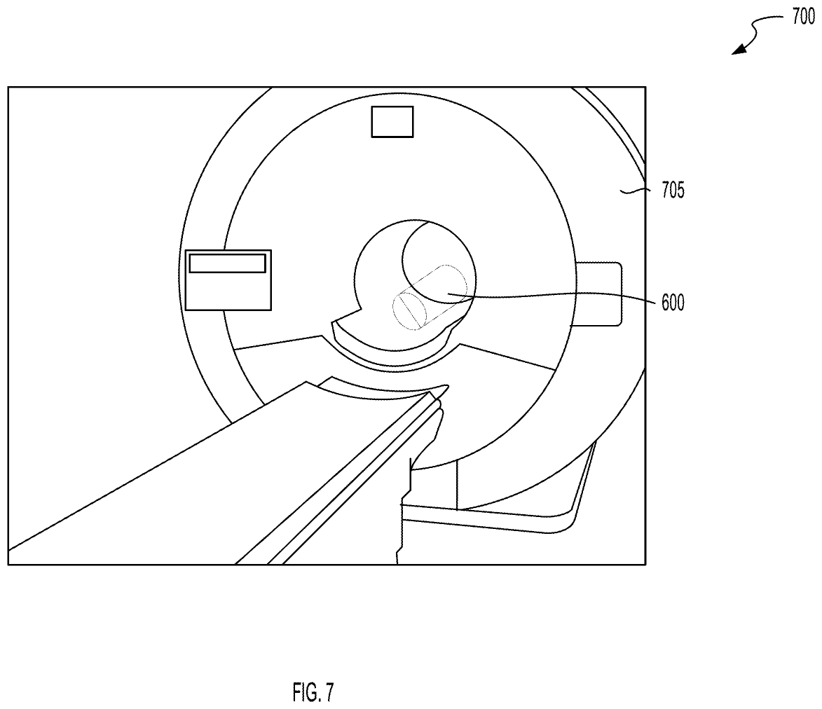

FIG. 7 illustrates a magnetic field monitoring system 700. The magnetic field monitoring system 700 can include a host system 705 (e.g., host MRI system, host MR system, MRI scanner, MRI system, MRI system, MR system, magnetic resonance imaging scanner, main system, main NMR system, main MRI system, etc.). The spherical assembly 500 of sensor assemblies 400 can be placed inside the host system 705 for the calibration measurement. The spherical assembly 500 of sensor assemblies 400 can be placed at the center of the magnet to reduce errors. The cylindrical assembly 600 of sensor assemblies 400 can be deployed alone as a calibration measurement. The cylindrical assembly 600 of sensor assemblies 400 can also be deployed during MRI scans of patients to monitor the gradient performance during the scans in real time. The physical placement of the cylindrical assembly 600 of sensor assemblies 400 is shown inside the host system 705 of FIG. 7. The sensor assemblies 400 can be integrated with the host system 705. For example, the sensor assemblies 400 can be imbedded in a patient bed of the host system 705. The host system 705 can generate a magnetic field. The host system 705 can include a magnetic resonance system. The host system 705 can provide a trigger to a magnetic field monitoring system 700.

The magnetic field monitoring system 700 can include a plurality of sensor assemblies 400 (e.g., as shown in FIGS. 6 and 7). A trigger signal from the host system 705 can synchronize the acquisition of data from the plurality of sensor assemblies 400 with the execution of the MRI protocol to capture the magnetic field during the image acquisition. An accurate time stamp for the data from the plurality of sensor assemblies 400 can be used to synchronize with the MRI data acquisition in the post-processing and image reconstruction.

The data from the plurality of sensor assemblies 400 may be used to identify the imperfections of the MRI system (e.g., MRI gradient system). This can help manufacturers of the host system 705 improve their scanners. For example, manufacturers can improve their scanners by identifying and replacing worn-out or defective magnets. The data from the plurality of sensor assemblies 400 may be directly fed to the host system 705 (e.g., MRI scanner) in real time to improve the MRI. Such feedback can be performed in several ways. For example, when significant error or imperfection is observed by the plurality of sensor assemblies 400 that would severely affect the quality of the image or indicate failure of the MRI equipment, the data from the plurality of sensor assemblies 400 can be reported to the operators and the scan may be halted and repeated. The data from the plurality of sensor assemblies 400 may show a gradual degradation of the gradient performance in comparison with the designed performance. The data from the plurality of sensor assemblies 400 may be used to correct for such degradation during the scans. For example, an MRI protocol may specify/require a gradient of certain strength. The plurality of sensor assemblies 400 can detect the actual gradient as lower than the designed value. Such data from the plurality of sensor assemblies 400 can be fed back to the host system 705 to boost the gradient. The data from the plurality of sensor assemblies 400 can detect the imbalance of the different gradients and subsequently update the gradient calibration files in the host system 705 so that the future scans can be corrected. The data from the plurality of sensor assemblies 400 can be used with the host system 705 to improve imaging and image quality.

The plurality of sensor assemblies 400 can be disposed apart from each other within the host system 705. Each of the plurality of sensor assemblies 400 can include the coil 415 wound around the sample 405. The sample 405 can include at least one of ¹H, ¹⁹F or 2D. Each of the plurality of sensor assemblies 400 can include the coil 415 wound around the sample holder 410. Each of the plurality of sensor assemblies 400 can include an integrated circuit (IC) (e.g., NMR ASIC 420) coupled with the coil 415. The IC can perform one or more MR measurements of the sample 405 using one or more pulse sequences (e.g., as shown in FIGS. 1-3). The one or more MR measurements can include at least one of pulse sequence execution, radio frequency (RF) pulse transmission, nuclear magnetic resonance (NMR) signal reception, amplification, or down conversion. The IC can be disposed between 30 cm and 100 cm from the sample 405. A distance between the sample 405 and the IC can be in a range of 2 cm to 5 cm. For example, the IC can be close to the sample 405 (e.g., between 2 cm and 5 cm) to form a compact sensor assembly 400.

The miniaturization of sensor assemblies 400 can allow for the placement of the plurality of sensor assemblies 400 in RF coil assemblies for MRI. For example, a head coil can contain several (e.g., 32) receiver coils housed in a structure around the patient's head. The plurality of sensor assemblies 400 can be installed inside the head coil structure at various positions without interfering with the normal operation of the head coil.

The plurality of sensor assemblies 400 can be used to improve MRI. For example, a large number of sensor assemblies 400 (e.g., 16 or 30) can be installed in the host system 705 to accurately characterize the performance of all gradients (e.g., X, Y, and Z) and the main magnetic field. This arrangement of the sensor assemblies 400 can be called the calibration set. The plurality of sensor assemblies 400 can be placed substantially uniformly around the expected sample (e.g., a patient's head). A small number of sensor assemblies 400 (e.g., 1-10) can be installed in an MRI coil to monitor the performance of the gradients to identify small deviations of the gradients from their nominal performance due to the aging of the electronics, temperature changes, or other power fluctuations. This arrangement of the sensor assemblies 400 can be called the monitor set. The magnetic field monitoring system 700 can include a calibration set, a monitoring set, or both. For example, the calibration set can be installed in an MRI coil so that the full characterization of the gradients and field is performed for all imaging experiments.

The plurality of sensor assemblies 400 can be arranged in a spherical configuration that is disposed within the host system 705. A center of the spherical configuration can be offset with respect to a magnet center of the host system 705. The center of the spherical configuration can be substantially at the center of a magnet (e.g., magnet center) of the host system 705. The plurality of sensor assemblies 400 can be arranged in a cylindrical configuration that is disposed within the host system 705. A center of the cylindrical configuration can be offset with respect to a magnet center of the host system 705. The plurality of sensor assemblies 400 can be embedded in a patient bed of a magnetic resonance imaging scanner.

The magnetic field monitoring system 700 can include the microcontroller 425. The microcontroller 425 can transmit and/or receive data. The microcontroller 425 can transmit the one or more pulse sequences to the IC. The microcontroller 425 can receive data from the IC. The data from the IC can include the one or more MR measurements of the sample 405. The microcontroller 425 can transmit data from the IC to the host system 705. The host system 705 can adjust parameters (e.g., settings) of the host system 705 in real time in response to the data from the IC. For example, the parameters of the host system 705 can include the magnetic field strength, acquisition time, position of a target (e.g., sample to be measured), transmitted RF pulses, pulse sequences, or others. The microcontroller 425 can be disposed between 30 cm and 100 cm from the sample 405.

The microcontroller 425 can process data from the IC. The data can include data from the data from the plurality of sensor assemblies 400. The microcontroller 425 can use the data from the plurality of sensor assemblies 400 for image processing. The microcontroller 425 can reconstruct an image of the target disposed in the host system 705.

The magnetic field monitoring system 700 can include the microcontroller 425. The microcontroller 425 can transmit data from the IC to a controller of the host system 705. The host system 705 can include a host computer or an external computer. The controller can process the data from the microcontroller 425. For example, the controller can process the data from the plurality of sensor assemblies 400. The controller can use the data from the plurality of sensor assemblies 400 for image processing. The controller can reconstruct an image of the target disposed in the host system 705.

The host system 705 can include the controller. The host system 705 can use frequency variation to perform image reconstruction. The frequency variation can include the instantaneous frequency, ω(t). The frequency variation can include the measured frequency and its time variation according to Equation 16. For example, the controller can analyze the one or more MR measurements of the sample 405 to determine a frequency variation. The host system 705 can used the measured frequency and its time variation according to Equation 16 to perform image reconstruction. The one or more MR measurements can include at least one of pulse sequence execution, radio frequency (RF) pulse transmission, nuclear magnetic resonance (NMR) signal reception, amplification, or down conversion. The controller can reconstruct an image of the target disposed in the host system 705 using the frequency variation.

The host system 705 can improve the MR measurements using gradient performance data. Gradient performance data can include the measured gradient at different positions and different times during the MRI experiment. For example, the controller can analyze the one or more MR measurements of the sample 405 to determine gradient performance data. The one or more MR measurements can include at least one of pulse sequence execution, radio frequency (RF) pulse transmission, nuclear magnetic resonance (NMR) signal reception, amplification, or down conversion. The controller can adjust parameters of the host system 705 in response to the gradient performance data. The parameters of the host system 705 can include the magnetic field strength, acquisition time, position of a target (e.g., sample to be measured), transmitted RF pulses, pulse sequences, or others. The plurality of sensor assemblies 400 can assess the performance of the gradient system. The gradient performance can be derived from ω(t).

The magnetic field monitoring system 700 can include a computer system (e.g., third computer system). The computer system can be separate from the plurality of sensor assemblies 400 and the host system 705. The computer system can receive data from the IC. The data can include the data from the plurality of sensor assemblies 400. The computer system can use the data from the plurality of sensor assemblies 400 for image processing. The computer system can reconstruct an image of the target disposed in the host system 705.

In some embodiments, the plurality of sensor assemblies 400 can be used to characterize (e.g., locally detect, measure and/or characterize at specific locations) the magnetic fields for an MRI experiment (e.g., protocol) by executing the protocol with only the plurality of sensor assemblies 400 in the scanner without the patient. The data from the plurality of sensor assemblies 400 can constitute the calibration data set for the protocol and can be used to improve the MRI technique of the protocol. The behavior of the magnet and gradients may be dependent on the protocol and thus such calibration data set can be collected for all the protocols to be calibrated.

In some embodiments, the plurality of sensor assemblies 400 of the calibration set can be installed in an MRI coil at various positions encompassing the sample (e.g., region of interest (ROI)). The magnetic field data (e.g., data from the plurality of sensor assemblies 400) can be acquired using the plurality of sensor assemblies 400 together with the MRI experiments. The magnetic field data can be used to improve the image reconstruction of the MRI protocol.

In some embodiments, the monitor set of the plurality of sensor assemblies 400 can be installed in the MRI coil to monitor the performance of gradients and magnetic field. For example, the plurality of sensor assemblies 400 can be placed strategically to be most sensitive to different gradients (X, Y, and/or Z) and the static field. To be sensitive to Gₓ, a sensor assembly 400 can be placed on the X axis (e.g., Y=0, Z=0, and X≠0). The data from the plurality of sensor assemblies 400 can be used to monitor the performance of the gradients (e.g., whether the observed gradient amplitudes is consistent with the designed value). The data from the plurality of sensor assemblies 400 can be used as an MRI quality check. The data from the plurality of sensor assemblies 400 can be used to improve the image reconstruction by using the observed gradient amplitudes.

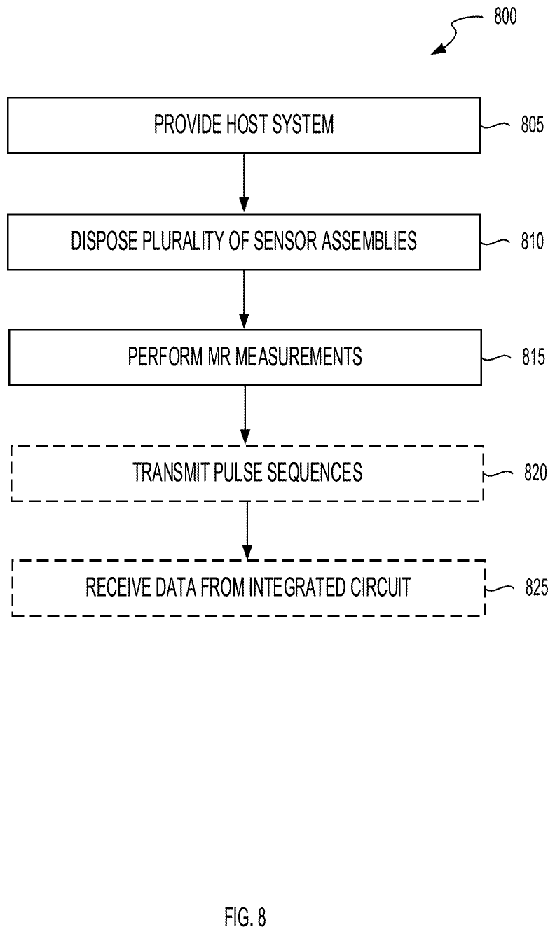

FIG. 8 illustrates a method of monitoring a magnetic field. In brief summary, the method 800 can include providing a host system (BLOCK 805). The method 800 can include disposing a plurality of sensor assemblies (BLOCK 810). The method 800 can include performing one or more MR measurements (BLOCK 815). The method 800 can include transmitting one or more pulse sequences (BLOCK 820). The method 800 can include receiving data from the integrated circuit (BLOCK 825).

The method 800 can include providing a host system (BLOCK 805). The host system (e.g., host MRI system, host MR system, MRI scanner, MRI system, MRI system, MR system, magnetic resonance imaging scanner, main system, main NMR system, main MRI system, etc.) can generate a magnetic field. For example, a spherical assembly of sensor assemblies can be placed inside the host system for the calibration measurement. The spherical assembly of sensor assemblies can be placed at the center of the magnet to reduce errors. In another example, a cylindrical assembly of sensor assemblies can be deployed alone as a calibration measurement. The cylindrical assembly of sensor assemblies can also be deployed during MRI scans of patients to monitor the gradient performance during the scans in real time. The physical placement of the cylindrical assembly of sensor assemblies is shown inside the host system. The sensor assemblies can be integrated with the host system, for example, imbedded in the patient bed of the host system. The host system can generate a magnetic field. The host system can include a magnetic resonance system.

The method 800 can include disposing a plurality of sensor assemblies (BLOCK 810). The method 800 can include disposing a plurality of sensor assemblies apart from each other within the host system. Each of the plurality of sensor assemblies can include a sample disposed in a sample holder and an integrated circuit (IC). The sample can include at least one of ¹H, ¹⁹F or ²D. The plurality of sensor assemblies can include one or more sensor assemblies 400.

The method 800 can include performing one or more MR measurements (BLOCK 815). The method 800 can include performing, by the IC, one or more MR measurements of the sample using one or more pulse sequences. The one or more MR measurements can include at least one of pulse sequence execution, radio frequency (RF) pulse transmission, nuclear magnetic resonance (NMR) signal reception, amplification, or down conversion.

The method 800 can include transmitting one or more pulse sequences (BLOCK 820). The method 800 can include transmitting, by a microcontroller, the one or more pulse sequences to the IC. A digital signal can be transmitted to the microcontroller for processing. The digital signal can be stored in the microcontroller or external memory. The digital signal can be transmitted to a host computer (e.g., an MRI console) to be used in image reconstruction. The microcontroller can process the NMR signal. The microcontroller can store the pulse sequences to be executed for the magnetic field measurement. The microcontroller can be coupled to the NMR ASIC via a digital link. The microcontroller can issue digital commands and timing clock signals to the NMR ASIC and/or peripheral components (e.g., RF switches). The microcontroller can issue timing clock signals to the NMR ASIC via the digital link. Examples of the microcontroller can include the PIC32 family by Microchip, C2000 family by Texas Instruments, or other ARM-based microcontroller products. Other chips such as FPGA, digital signal processors (DSP) may also be used instead of microcontroller.

The method 800 can include receiving data from the integrated circuit (BLOCK 825). The method 800 can include receiving, by the microcontroller, data from the IC comprising the one or more MR measurements of the sample. The one or more MR measurements (e.g., measurement process or operation) can include/involve at least one of pulse sequence execution, radio frequency (RF) pulse transmission, nuclear magnetic resonance (NMR) signal reception, amplification, or down conversion.

In some embodiments, the method 800 can include processing, by the microcontroller, data from the IC in real time. In some embodiments, the method 800 can include post-processing, by a controller, data from the IC. In some embodiments, the method 800 can include reconstructing, by the controller, an image of a target disposed in the host system. In some embodiments, the method 800 can include receiving, by a computer system, data from the IC and reconstructing, by the computer system, an image of the target disposed in the host system. In some embodiments, the method 800 can include receiving, by a computer system, data from the IC and reconstructing, by one or more computer servers physically remote (e.g., located in a separate room, separate building, etc.) from the host system, an image of the target disposed in the host system. In some embodiments, the method 800 can include receiving, by a computer system, data from the IC and reconstructing, by a cloud-based system, an image of the target disposed in the host system. For example, the reconstruction may be also performed by a computer substantially away from the MR system acquiring the data, for example, on a computing cloud server or a cloud-based system.

In some embodiments, the method 800 can include using frequency variation to perform image reconstruction. For example, the method 800 can include analyzing, by a controller, the one or more MR measurements of the sample to determine a frequency variation. The method 800 can include reconstructing, by the controller, an image of a target disposed in the host system using the frequency variation.

In some embodiments, the method 800 can improve the MR measurements using gradient performance data. For example, the method 800 can include analyzing, by a controller, the one or more MR measurements of the sample to determine gradient performance data. The method 800 can include adjusting, by the controller, parameters (e.g., settings) of the host system in response to the gradient performance data. For example, the parameters of the host system can include the magnetic field strength, acquisition time, position of a target (e.g., sample to be measured), transmitted RF pulses, pulse sequences, or others.

In some embodiments, the method 800 can include characterizing (e.g., measuring, calculating and/or determining) a magnetic field gradient. For example, the method 800 can include disposing a first sensor assembly of the plurality of sensor assemblies and a second sensor assembly of the plurality of sensor assemblies along an axis of the host system. The method 800 can include characterizing the magnetic field gradient along the axis of the host system.

In some embodiments, the method 800 can include transmitting, by the microcontroller, data from the IC to the host system. The host system can adjust parameters (e.g., settings) of the host system in real time in response to the data from the IC. For example, the parameters of the host system can include the magnetic field strength, acquisition time, position of a target (e.g., sample to be measured), transmitted RF pulses, pulse sequences, or others.

Embodiments of the subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatus. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. Moreover, while a computer storage medium may not be a propagated signal, a computer storage medium can be a source or destination of computer program instructions encoded in an artificially generated propagated signal. The computer storage medium can also be, or be included in, one or more separate components or media (e.g., multiple CDs, disks, or other storage devices).

The operations described in this specification can be performed by a data processing apparatus on data stored on one or more computer-readable storage devices or received from other sources. The term “data processing apparatus” or “computing device” encompasses various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a circuit, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more circuits, subprograms, or portions of code). A computer program can be deployed to be executed on one computer or on multiple computers that are located at one site or distributed across multiple sites and interconnected by a communication network.

Processors suitable for the execution of a computer program include, by way of example, microprocessors, and any one or more processors of a digital computer. A processor can receive instructions and data from a read only memory or a random access memory or both. The elements of a computer are a processor for performing actions in accordance with instructions and one or more memory devices for storing instructions and data. A computer can include, or be operatively coupled to receive data from or transfer data to, or both, one or more mass storage devices for storing data, e.g., magnetic, magneto optical disks, or optical disks. A computer need not have such devices. Moreover, a computer can be embedded in another device, e.g., a personal digital assistant (PDA), a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, implementations of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

The implementations described herein can be implemented in any of numerous ways including, for example, using hardware, software or a combination thereof. When implemented in software, the software code can be executed on any suitable processor or collection of processors, whether provided in a single computer or distributed among multiple computers.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

A computer employed to implement at least a portion of the functionality described herein may comprise a memory, one or more processing units (also referred to herein simply as “processors”), one or more communication interfaces, one or more display units, and one or more user input devices. The memory may comprise any computer-readable media, and may store computer instructions (also referred to herein as “processor-executable instructions”) for implementing the various functionalities described herein. The processing unit(s) may be used to execute the instructions. The communication interface(s) may be coupled to a wired or wireless network, bus, or other communication means and may therefore allow the computer to transmit communications to or receive communications from other devices. The display unit(s) may be provided, for example, to allow a user to view various information in connection with execution of the instructions. The user input device(s) may be provided, for example, to allow the user to make manual adjustments, make selections, enter data or various other information, or interact in any of a variety of manners with the processor during execution of the instructions.

The various methods or processes outlined herein may be coded as software that is executable on one or more processors that employ any one of a variety of operating systems or platforms. Additionally, such software may be written using any of a number of suitable programming languages or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the solution discussed above. The computer readable medium or media can be transportable, such that the program or programs stored thereon can be loaded onto one or more different computers or other processors to implement various aspects of the present solution as discussed above.

The terms “program” or “software” are used herein to refer to any type of computer code or set of computer-executable instructions that can be employed to program a computer or other processor to implement various aspects of embodiments as discussed above. One or more computer programs that when executed perform methods of the present solution need not reside on a single computer or processor, but may be distributed in a modular fashion amongst a number of different computers or processors to implement various aspects of the present solution.

Computer-executable instructions may be in many forms, such as program modules, executed by one or more computers or other devices. Program modules can include routines, programs, objects, components, data structures, or other components that perform particular tasks or implement particular abstract data types. The functionality of the program modules can be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

Any references to implementations or elements or acts of the systems and methods herein referred to in the singular can include implementations including a plurality of these elements, and any references in plural to any implementation or element or act herein can include implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementations,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Elements other than ‘A’ and ‘B’ can also be included.

The systems and methods described herein may be embodied in other specific forms without departing from the characteristics thereof. The foregoing implementations are illustrative rather than limiting of the described systems and methods.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

The systems and methods described herein may be embodied in other specific forms without departing from the characteristics thereof. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

1. A magnetic field monitoring system, comprising:
a host system that generates a magnetic field; and
a plurality of sensor assemblies disposed apart from each other within the host system, each of the plurality of sensor assemblies comprising:
a coil wound around a sample; and
an integrated circuit (IC) coupled with the coil, the IC configured to perform one or more MR measurements of the sample using one or more pulse sequences.

2. The magnetic field monitoring system of claim 1, wherein the host system is a magnetic resonance system.

3. The magnetic field monitoring system of claim 2, wherein the host system provides a trigger to the magnetic field monitoring system.

4. The magnetic field monitoring system of claim 1, wherein the sample comprises at least one of ¹H, ¹⁹F or ²D.

5. The magnetic field monitoring system of claim 1, further comprising a microcontroller configured to:
transmit the one or more pulse sequences to the IC; and
receive data from the IC comprising the one or more MR measurements of the sample.

6. The magnetic field monitoring system of claim 1, further comprising a microcontroller configured to transmit data from the IC to the host system, the host system configured to adjust parameters of the host system in real time in response to the data from the IC.

7. The magnetic field monitoring system of claim 1, further comprising a microcontroller configured to:
process data from the IC; and
reconstruct an image of a target disposed in the host system.

8. The magnetic field monitoring system of claim 1, further comprising:
a microcontroller configured to transmit data from the IC to a controller of the host system, the controller configured to:
process the data from the microcontroller; and
reconstruct an image of a target disposed in the host system.

9. The magnetic field monitoring system of claim 1, further comprising:
a computer system configured to:
receive data from the IC; and
reconstruct an image of a target disposed in the host system.

10. The magnetic field monitoring system of claim 1, wherein the one or more MR measurements include at least one of pulse sequence execution, radio frequency (RF) pulse transmission, nuclear magnetic resonance (NMR) signal reception, amplification, or down conversion.

11. The magnetic field monitoring system of claim 1, wherein the plurality of sensor assemblies is arranged in a spherical or cylindrical configuration that is disposed within the host system.

12. The magnetic field monitoring system of claim 11, wherein a center of the spherical or cylindrical configuration is substantially at a center of a magnet of the host system.

13. The magnetic field monitoring system of claim 1, wherein the plurality of sensor assemblies is embedded in a patient bed of a magnetic resonance imaging scanner.

14. The magnetic field monitoring system of claim 1, wherein the sample is disposed between 30 cm and 100 cm from at least one of: the IC or a microcontroller.

15. The magnetic field monitoring system of claim 1, wherein a distance between the sample and the IC is in a range of 2 cm to 5 cm.

16. The magnetic field monitoring system of claim 1, wherein the host system comprises a controller configured to:
analyze the one or more MR measurements of the sample to determine a frequency variation; and
reconstruct an image of a target disposed in the host system using the frequency variation.

17. The magnetic field monitoring system of claim 1, wherein the host system comprises a controller configured to:
analyze the one or more MR measurements of the sample to determine gradient performance data; and
adjust parameters of the host system in response to the gradient performance data.

18. A method of monitoring a magnetic field, comprising:
providing a host system that generates a magnetic field;
disposing a plurality of sensor assemblies apart from each other within the host system, each of the plurality of sensor assemblies comprising a sample disposed in a sample holder and an integrated circuit (IC); and
performing, by the IC, one or more MR measurements of the sample using one or more pulse sequences.

19. The method of claim 18, further comprising:
transmitting, by a microcontroller, the one or more pulse sequences to the IC; and
receiving, by the microcontroller, data from the IC comprising the one or more MR measurements of the sample.

20. The method of claim 18, further comprising at least one of:
processing, by a microcontroller, data from the IC in real time;
post-processing, by a controller, the data from the IC; or
reconstructing, by the controller, an image of a target disposed in the host system.

21-30. (canceled)
